(19) United States
(12) Patent Application Publication
(10) Pub. No.: US 2009/0261447 A1
(43) Pub. Date: Oct. 22, 2009

(54) SEMICONDUCTOR INTEGRATED CIRCUIT

(75) Inventors: Takeshi Ikeda, Tokyo (JP); Hiroshi Miyagi, Yokohama-shi (JP)

Correspondence Address: CONNOLLY BOVE LODGE & HUTZ LLP, 1875 EYE STREET, N.W., SUITE 1100, WASHINGTON, DC, 20006, US

(73) Assignee: NSC CO., LTD., Tokyo (JP)

(21) Appl. No.: 12/392,611

(22) Filed: Feb. 25, 2009

(30) Foreign Application Priority Data
Feb. 26, 2008 (JP) JP2008-044006

(51) Int. Cl. H01L 25/16

(52) U.S. Cl. 257/500; 257/E25.029

(57) ABSTRACT

Signal lines (13) and (14) to be used for supplying a signal between an analog circuit and a digital circuit are provided in different regions from power-ground lines (11) and (12) to be used for supplying a power to the analog circuit and the digital circuit in such a manner that the signal lines (13) and (14) do not cross the power-ground lines (11) and (12). For example, the power-ground lines (11) and (12) are provided along an outer periphery of a semiconductor chip (10) and the analog circuit and the digital circuit are disposed on the inside of the power-ground lines (11) and (12), and the signal lines (13) and (14) are provided between the analog circuit and the digital circuit.

### BACKGROUND OF THE INVENTION

1. Field of the Invention

The present invention relates to a semiconductor integrated circuit, and more particularly to a semiconductor integrated circuit in which an analog circuit and a digital circuit are provided together on the same semiconductor chip.

2. Description of the Related Art

A technique for manufacturing a semiconductor device includes a bipolar technique using silicon, a GaAs technique of a compound semiconductor using gallium arsenide, a CMOS (Complementary Metal Oxide Semiconductor) technique and the like. In particular, the CMOS technique has a feature that a consumed power is small, an operation can also be carried out at a low voltage, a high speed operation can be carried out because of a microfabrication and a manufacturing cost can be reduced, and is currently employed most often in the semiconductor device.

Conventionally, the bipolar technique or the GaAs technique is often used in an RF (Radio Frequency) circuit (an analog circuit portion) for receiving and processing a radio frequency signal, and the CMOS technique has rarely been used. The reason is that the CMOS technique is mainly suitable for a digital circuit and an analog circuit fabricated by the CMOS technique cannot obtain a radio frequency characteristic having sufficiently excellent S/N.

However, an improvement in the CMOS technique has recently been progressed. In Bluetooth to be a short distance wireless data communication technology using a 2.4 GHz band or a communicating semiconductor chip intended for a wireless LAN using a 5 GHz band, an analog circuit portion introducing the CMOS technique has been offered comparatively often. In recent years, a trial for introducing the CMOS technique into an analog circuit portion in an FM or AM frequency band has been vigorously carried out also in a semiconductor chip which is intended for a receiver such as a radio or a television or a semiconductor chip which is intended for a transmitter such as an FM transmitter.

When the analog circuit portion can be changed into a CMOS, it is possible to integrate, into a single chip, an RF circuit (an analog circuit portion) for transmitting/receiving a radio frequency signal and a baseband signal processing circuit (a digital circuit portion) for carrying out a digital signal processing over a signal to be transmitted/received, for example. More specifically, although an analog LSI and a digital LSI have conventionally been independent, they can be collected and integrated as an analog-digital mixing LSI. By utilizing the analog-digital mixing LSI, it is possible to decrease the number of analog passive components.

With the change of the analog circuit portion into the CMOS, recently, there have been increased the number of examples in which a function realized conventionally by an analog circuit is implemented by using a digital circuit such as a DSP (Digital Signal Processor) which is suitable for the CMOS technique. For example, there has also been proposed a technique for carrying out an AGC (Automatic Gain Control) processing for an antenna damping circuit and an LNA (Low Noise Amplifier) which are analog circuit portions as a digital signal processing by using the DSP in a receiver including an AGC circuit for regulating a gain of a radio frequency signal received through an antenna by controlling a quantity of attenuation in an antenna damping circuit or a gain of the LNA or the like (for example, see Patent Document 1).

Patent Document 1: WO2005/053171 Publication

In the technique described in the Patent Document 1, a level of a broadband RF signal output from the LNA, a level of an intermediate band IF (Intermediate Frequency) signal output from an IF amplifier and a level of a narrowband IF signal output from an IF filter are detected and converted into digital signals respectively, and the DSP determines a propriety of the gain control and gain control quantities in the antenna damping circuit and the LNA based on the signal level in each of the bands.

In the analog-digital mixing integrated circuit described above, the analog circuit and the digital circuit are disposed closer to each other as compared with the case in which they are constituted on separate chips. For this reason, a great noise of the digital circuit often enters the analog circuit having a high sensitivity. In this case, there is a possibility that a characteristic of the analog signal might be deteriorated greatly. Accordingly, how to reduce a coupling noise of the analog circuit and the digital circuit is very important.

In many cases, therefore, a front end portion such as an RF circuit constituted by an analog circuit and a baseband signal processing circuit and an AGC control circuit constituted by a digital circuit such as a DSP are separated into an analog circuit region and a digital circuit region over a chip layout and are thus disposed. Furthermore, a guard ring is often formed in a boundary portion between the analog circuit region and the digital circuit region (for example, see Patent Document 2).

Patent Document 2: Japanese Laid-Open Patent Publication No. 2003-37172

As shown in FIG. 3, there is also a method of forming a power line or a ground line (which will be hereinafter referred to as a “power-ground line”) in place of the guard ring in a boundary portion between an analog circuit region AR and a digital circuit region DR. More specifically, in the example shown in FIG. 3, power-ground lines 50 and 51 to be used for supplying a power to an analog circuit and a digital circuit also serve to separate the analog circuit from the digital circuit. 50 denotes an analog power-ground line and 51 denotes a digital power-ground line.

In the case in which the power-ground lines 50 and 51 are used for an analog-digital separation as shown in FIG. 3, a signal line 52 for supplying a control signal from a DSP 54 to an analog circuit of a front end portion 55 through a DAC portion 57 crosses the power-ground lines 50 and 51, for example. Moreover, a signal line 53 for supplying a signal from an analog circuit such as an IF amplifier 56 to the DSP 54 through an ADC portion 58 also crosses the power-ground lines 50 and 51. More specifically, as shown in FIG. 4, a semiconductor chip is set to have a multilayer structure constituted by a plurality of layers, the power-ground lines 50 and 51 and the signal lines 52 and 53 are provided in different wiring layers from each other, and the signal lines 52 and 53 are provided to cross the power-ground lines 50 and 51.

### DISCLOSURE OF THE INVENTION

Although the power-ground lines 50 and 51 and the signal lines 52 and 53 are provided in the different wiring layers from each other in the prior art, however, their positions are very close to each other in portions where the wiring cross each other. For this reason, there is a problem in that a power noise is carried on a control signal flowing to the signal line 52 and is scattered into the analog circuit region AR. The problem is caused also in the case in which a signal processed in a digital circuit is D/A converted and the D/A converted signal is supplied to an analog circuit.

Moreover, the power noise is also carried on an analog signal supplied from the IF amplifier 56 to the ADC portion 58 when crossing the power-ground lines 50 and 51. For this reason, there is a problem in that S/N of the analog signal supplied to the DAC portion is deteriorated and an A/D conversion into a correct value cannot be performed in some cases.

In order to solve the problems, it is an object of the present invention to eliminate a drawback that a power noise is carried on a signal supplied between an analog circuit and a digital circuit in an analog-digital mixing semiconductor chip in which the analog circuit and the digital circuit are separated from each other and are thus disposed.

In order to attain the object, in the present invention, a signal line to be used for supplying a signal between an analog circuit and a digital circuit which are disposed in separated regions on the same semiconductor chip is provided in a different region from a power-ground line to be used for supplying a power to the analog circuit and the digital circuit in such a manner that the signal line and the power-ground line do not cross each other.

According to the present invention having the structure described above, the signal line and the power-ground line do not cross each other. Therefore, it is possible to eliminate a drawback that a power noise is carried on a signal flowing to the signal line from the power-ground line. Consequently, it is possible to prevent a state in which S/N of the signal itself flowing through the signal line is deteriorated by the power noise and a state in which the power noise superposed on the signal flowing through the signal line is scattered into the analog circuit region. Thus, it is possible to enhance the S/N.

### BRIEF DESCRIPTION OF THE DRAWINGS

FIG. 1 is a diagram showing an example of a circuit layout of a semiconductor integrated circuit provided on a semiconductor chip according to the present embodiment,

FIG. 2 is a diagram showing an example of a functional structure of a radio receiver implemented by the semiconductor integrated circuit illustrated in FIG. 1,

FIG. 3 is a diagram showing a conventional semiconductor integrated circuit in which a power-ground line is formed in a boundary portion between an analog circuit region and a digital circuit region, and

FIG. 4 is a diagram showing an example of a conventional structure in which a signal line and a power-ground line cross each other through different wiring layers in a semiconductor chip having a multilayer structure.

### DETAILED DESCRIPTION OF THE PREFERRED EMBODIMENTS

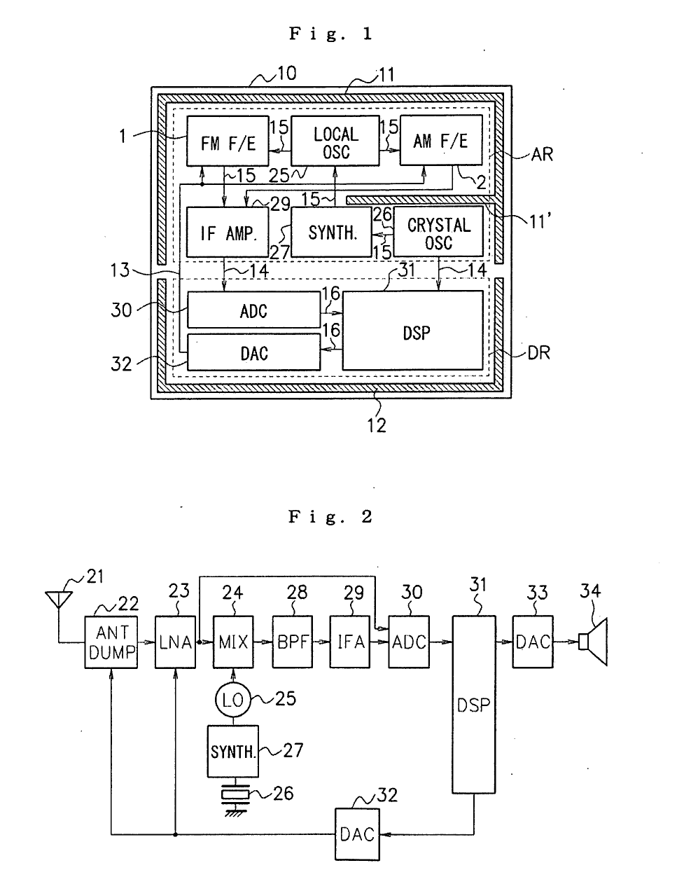

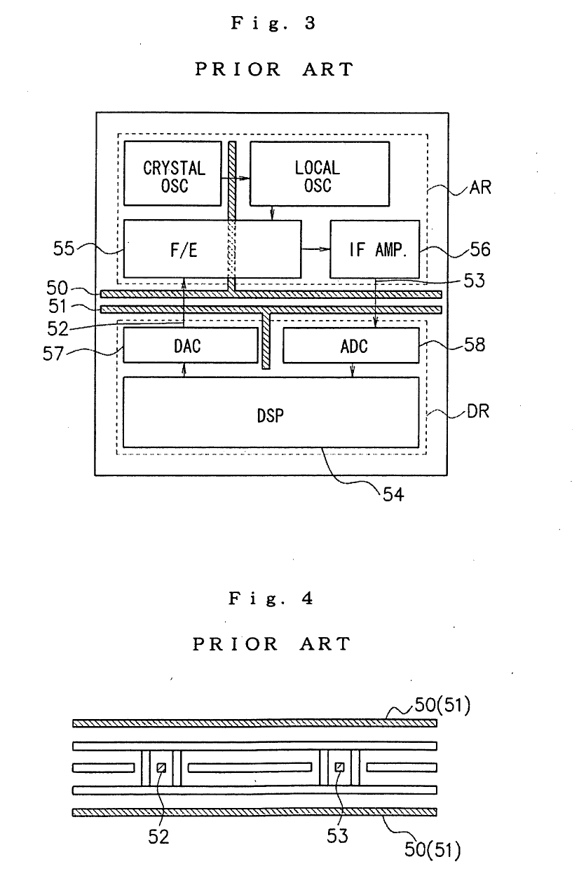

An embodiment according to the present invention will be described below with reference to the drawings. FIG. 1 is a diagram showing an example of a circuit layout of a semiconductor integrated circuit provided on a semiconductor chip 10 according to the present embodiment. For the circuit layout, a plane layout having the semiconductor chip 10 seen from above is shown. The semiconductor integrated circuit according to the present embodiment is integrated in the single semiconductor chip 10 through a CMOS (Complementary Metal Oxide Semiconductor) process, for example.

FIG. 2 is a diagram showing an example of a functional structure of a radio receiver implemented by the semiconductor integrated circuit illustrated in FIG. 1. A structure of a radio receiver for carrying out an AGC processing for an antenna damping circuit and an LNA by using a DSP is shown as an example. In FIG. 2, circuit structures other than an antenna 21 are integrated in the semiconductor chip 10 of FIG. 1.

In FIG. 2, an antenna damping circuit 22 controls an RF signal received through the antenna 21 (a broadband broadcast wave signal including a desirable wave frequency and a disturbing wave frequency) to have a degree of attenuation which is set variably in response to a control signal supplied from a D/A converting circuit 32. An LNA 23 amplifies the RF signal passing through the antenna damping circuit 22 with a low noise. A gain of the LNA 23 is controlled in response to a control signal supplied from the D/A converting circuit 32.

The signal amplified by the LNA 23 is supplied to a frequency converting circuit 24 and an A/D converting circuit 30. The frequency converting circuit 24 mixes an RF signal supplied from the LNA 23 with a local oscillating signal supplied from a local oscillating circuit 25 and carries out a frequency conversion, thereby generating and outputting an IF signal. The local oscillating signal is generated by a frequency synthesizer 27 such as a PLL (Phase Locked Loop) and the local oscillating circuit 25 by using a signal having a reference frequency which is output from a crystal oscillator 26, for example.

The IF signal output from the frequency converting circuit 24 is subjected to a band limitation in a BPF 28 and is thus changed into a narrowband IF signal containing only a desirable frequency. More specifically, the BPF 28 carries out the band limitation over the IF signal supplied from the frequency converting circuit 24 and extracts the narrowband IF signal containing only the desirable wave frequency.

An IF amplifier 29 amplifies the narrowband IF signal output from the BPF 28. The A/D converting circuit 30 analog-digital converts the IF signal output from the IF amplifier 29. Thus, a narrowband digital IF signal converted into digital data is input to a DSP 31. The DSP 31 demodulates, into a baseband signal, the narrowband digital IF signal input from the A/D converting circuit 30, and outputs the baseband signal to an outside.

Moreover, the A/D converting circuit 30 analog-digital converts the RF signal output from the LNA 23. The RF signal output from the LNA 23 is a broadband RF signal containing both a desirable frequency and a disturbing frequency. A broadband digital RF signal converted into digital data by the A/D converting circuit 30 is also supplied to the DSP 31.

The DSP 31 detects receiving electric field strengths of the narrowband IF signal and the broadband RF signal which are input from the A/D converting circuit 30, respectively. The DSP 31 controls a gain of a received signal through gain control portions (the antenna damping circuit 22 and the LNA 23) in an RF stage based on the receiving electric field strengths of the narrowband IF signal and the broadband RF signal which are detected.

More specifically, the DSP 31 generates control data for controlling the gain of the RF stage by referring to control table information which is not shown, for example. The control data are supplied to the D/A converting circuit 32. The D/A converting circuit 32 converts the control data supplied from the DSP 31 into an analog signal and outputs the analog signal to the antenna damping circuit 22 and the LNA 23. Consequently, a quantity of attenuation of the antenna damping circuit 22 and a gain of the LNA 23 are controlled based on the control signal supplied from the D/A converting circuit 32.

Moreover, the DSP 31 demodulates, into a baseband signal, the narrowband IF signal input from the A/D converting circuit 30 and outputs the baseband signal to a D/A converting circuit 33. The D/A converting circuit 33 converts a digital signal supplied from the DSP 31 into an analog signal and outputs the analog signal to a speaker 34.

Next, an example of a circuit layout for each of the structures 22 to 32 of a radio receiver having the structure shown in FIG. 2 will be described with reference to FIG. 1. The antenna damping circuit 22, the LNA 23, the frequency converting circuit 24 and the BPF 28 in FIG. 2 are collectively disposed in an FM front end portion 1 and an AM front end portion 2 in FIG. 1. In FIG. 2, the antenna damping circuit 22, the LNA 23, the frequency converting circuit 24 and the BPF 28 are schematically shown one by one. Actually, they are present for FM and AM, respectively. They are collectively disposed for. the FM and the AM in the FM front end portion 1 and the AM front end portion 2, respectively.

In FIG. 1, all of the FM front end portion 1, the AM front end portion 2, the local oscillating circuit 25, the crystal oscillator 26, the synthesizer 27 and the IF amplifier 29 are analog circuits and are disposed in an analog circuit region AR of the semiconductor chip 10. On the other hand, all of the A/D converting circuit 30, the DSP 31 and the D/A converting circuit 32 are digital circuits and are disposed in a digital circuit region DR of the semiconductor chip 10. As shown in FIG. 1, the analog circuit region AR and the digital circuit region DR in the semiconductor chip 10 are set into different regions from each other.

An analog power-ground line 11 is provided along an outer periphery of the semiconductor chip 10 over a plane layout of the semiconductor chip 10 seen from above around the analog circuit region AR (excluding a partial power-ground line 11′). The analog power-ground line 11 is used for supplying a power to the analog circuit in the analog circuit region AR.

Similarly, a digital power-ground line 12 is provided along the outer periphery of the semiconductor chip 10 over the plane layout of the semiconductor chip 10 around the digital circuit region DR. The digital power-ground line 12 is used for supplying a power to the digital circuit in the digital circuit region DR.

The power-ground lines 11 and 12 are disposed along the outer periphery of the semiconductor chip 10 so that the analog and digital circuits are disposed on the inside of the power-ground lines 11 and 12. Consequently, a power is supplied from the power-ground lines 11 and 12 provided along the outer periphery of the semiconductor chip 10 to the analog and digital circuits which are disposed therein.

On the other hand, a signal line 13 to be used for supplying a signal from the digital circuit toward the analog circuit (either a signal processed by the digital circuit and supplied to the analog circuit or a control signal supplied from the digital circuit to the analog circuit in order to cause the digital circuit to control the analog circuit) and a signal line 14 to be used for supplying a signal from the analog circuit toward the digital circuit are provided to connect required circuit structures in a region on the inside of the power-ground lines 11 and 12 over the plane layout of the semiconductor chip 10.

Moreover, a signal line 15 to be used for supplying a signal in the analog circuit region AR and a signal line 16 to be used for supplying a signal in the digital circuit region DR are also provided to connect required circuit structures in the region on the inside of the power-ground lines 11 and 12 over the plane layout of the semiconductor chip 10.

In the present embodiment, the signal lines 13 and 14 to be used for supplying a signal between the analog circuit and the digital circuit which are disposed with the regions separated over the same semiconductor chip 10 are provided in different regions from the power-ground lines 11 and 12 to be to used for supplying a power to the analog circuit and the digital circuit over the plane layout of the semiconductor chip 10 in such a manner that the signal lines 13 and 14 do not cross the power-ground lines 11 and 12 (in different wiring layers).

Furthermore, the signal line 15 to be used for supplying a signal in the analog circuit region AR and the signal line 16 to be used for supplying a signal 15 the digital circuit region DR are also provided in the same manner. More specifically, it is preferable that the signal lines 15 and 16 should be provided in different regions from the power-ground lines 11 and 12 over the plane layout of the semiconductor chip 10. Although the signal lines 13 to 16 are provided so as not to cross the power-ground lines 11 and 12, the signal lines 13 and 15 may cross each other in the analog circuit region AR.

In the example of FIG. 1, most of the power-ground lines 11 and 12 are provided in the vicinity of the outer periphery of the semiconductor chip 10 along the outer periphery thereof, and the partial analog power-ground line 11′ is provided in the semiconductor chip 10. More specifically, the partial analog power-ground 11′ is provided in the semiconductor chip 10 in order to supply a power to the synthesizer 27 disposed in an almost central portion of the analog circuit region AR. Also in this case, the signal lines 13 to 16 are provided in the different regions from the power-ground line 11′ over the plane layout of the semiconductor chip 10 in such a manner that the power-ground line 11′ does not cross the signal lines 13 to 16.

In the case in which the partial power-ground line 11′ is provided in the semiconductor chip 10, thus, it is preferable that the signal lines 13 to 16 should be prevented from crossing the power-ground line 11′ and wiring lengths of the signal lines 13 to 16 should be prevented from being unnecessarily long to make a detour around the power-ground line 11′. For this purpose, it is preferable that the power-ground lines 11, 11′ and 12 should not be provided in a corresponding region to a boundary between the analog circuit region AR and the digital circuit region DR over the plane layout of the semiconductor chip 10 but be provided in regions other than the corresponding region to the boundary.

As described above in detail, in the present embodiment, the signal lines 13 to 16 are provided in the different regions from the power-ground lines 11, 11′ and 12 in such a manner that the power-ground lines 11, 11′ and 12 do not cross the signal lines 13 to 16. Because of the wiring layout, it is possible to eliminate a drawback that a power noise is carried on the signal flowing to the signal lines 13 to 16 through the power-ground lines 11, 11′ and 12. Consequently, it is possible to prevent a state in which the power noise is scattered into the analog circuit region AR through the signal flowing in the signal line 13 and a state in which the S/N of the signal itself flowing through the signal lines 13 to 16 is deteriorated by the power noise, for example. Thus, it is possible to enhance the S/N.

The arrangement shown in FIG. 1 is only illustrative and the present invention is not restricted thereto.

While the description has been given to the example in which the semiconductor integrated circuit according to the present embodiment is applied to the radio receiver in the embodiment, the application example is not restricted thereto. More specifically, any semiconductor integrated circuit employing a CMOS process for mounting an analog circuit and a digital circuit together with regions separated from each other can also be applied to apparatuses other than the radio receiver.

In addition, the embodiment is only illustrative for a concreteness to carry out the present invention and the technical range of the present invention should not be construed to be restrictive. In other words, the present invention can be carried out in various forms without departing from the spirit or main features thereof.

### INDUSTRIAL APPLICABILITY

The present invention is useful for a semiconductor integrated circuit in which an analog circuit and a digital circuit are provided together on the same semiconductor chip.

This application is based on Japanese Patent Application No. 2008-044006 filed on Feb. 26, 2008, the contents of which are incorporated hereinto by reference.

What is claimed is:

1. A semiconductor integrated circuit having an analog circuit and a digital circuit provided together on the same semiconductor chip,
wherein the semiconductor chip includes an analog circuit region and a digital circuit region, the analog circuit is disposed in the analog circuit region, and the digital circuit is disposed in the digital circuit region, and
a signal line to be used for supplying a signal between the analog circuit and the digital circuit is provided in a different region from a power-ground line to be used for supplying a power to the analog circuit and the digital circuit over a plane layout of the semiconductor chip seen from above in such a manner that the signal line does not cross the power-ground line.

2. The semiconductor integrated circuit according to claim 1, wherein the power-ground line is provided in a region other than a corresponding region to a boundary between the analog circuit region and the digital circuit region over the plane layout of the semiconductor chip and the signal line is provided in a different region from the power-ground line.

3. The semiconductor integrated circuit according to claim 2, wherein the power-ground line is wholly or partially provided along an outer periphery of the semiconductor chip over the plane layout of the semiconductor chip, and the signal line is provided in a different region from the power-ground line.

4. The semiconductor integrated circuit according to claim 1, wherein the analog circuit and the digital circuit are constituted by a CMOS process.

5. The semiconductor integrated circuit according to claim 1, wherein the digital circuit includes a DSP.
